(19) United States
(12) Patent Application Publication
(10) Pub. No.: US 2009/0230514 A1
(43) Pub. Date: Sep. 17, 2009

(54) Method of manufacturing nitride semiconductor device

(75) Inventor: Shinichi Kohda, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/219,691

(22) Filed: Jul. 25, 2008

(30) Foreign Application Priority Data
Jul. 27, 2007 (JP) 2007-196423

(51) Int. Cl. H01L 29/20; H01L 21/26; H01L 21/20; H01L 21/304

(52) U.S. Cl. 257/615; 438/796; 438/479; 438/690; 257/E21.09; 257/E21.328; 257/E21.237; 257/E29.089

(57) ABSTRACT

A method of manufacturing a nitride semiconductor device includes the steps of: growing a group III nitride semiconductor layer on a substrate; forming a processed region in the substrate with a laser beam; and reducing the thickness of the substrate thereby spontaneously dividing the substrate from the processed region by the internal stress of the substrate. The substrate may be a sapphire substrate or an SiC substrate.

### BACKGROUND OF THE INVENTION

1. Field of the Invention

The present invention relates to a method of manufacturing a nitride semiconductor device having a structure obtained by forming a group III nitride semiconductor layer on a substrate. Group III nitride semiconductors are group III-V semiconductors employing nitrogen as a group V element, and typical examples thereof include aluminum nitride (AlN), gallium nitride (GaN) and indium nitride (InN), which can be generally expressed as AlₓIn_{y}Ga_{1-x-y}N (0≦x≦1, 0≦y≦1 and 0≦x+y≦1).

2. Description of Related Art

Devices employing nitride semiconductors include light emitting devices such as a blue light emitting diode and a laser diode, transistors such as a power transistor and a high electron mobility transistor, and the like. Such a nitride semiconductor device is prepared by growing a group III nitride semiconductor such as GaN on a sapphire substrate, for example. More specifically, a GaN semiconductor is grown on a sapphire wafer. Thereafter the sapphire wafer is polished and reduced in thickness to about 80 μm, for example, and thereafter divided into individual chips.

The sapphire wafer is divided through the steps of converging a laser beam into the sapphire wafer and forming a processed region (modified region) in the sapphire wafer by multiphoton absorption caused on a focal point and thereafter dividing the sapphire wafer along the processed region by applying external force to the sapphire wafer (EP 1498216A1)

### SUMMARY OF THE INVENTION

When a substrate (sapphire substrate, for example) provided with a film of a group III nitride semiconductor (GaN semiconductor, for example) is polished and reduced in thickness, the substrate is warped due to the stress thereof. Therefore, the substrate is so hard to handle that the same may be broken in the process of manufacturing a nitride semiconductor device.

An object of the present invention is to provide a method of manufacturing a nitride semiconductor device capable of reducing the thickness of a substrate and of dividing the substrate while suppressing or preventing breakage of the substrate in the process of manufacturing the nitride semiconductor device.

A method of manufacturing a nitride semiconductor device according to one aspect of the present invention includes the steps of: growing a group III nitride semiconductor layer on a substrate; forming a processed region in the substrate with a laser beam; and reducing the thickness of the substrate thereby spontaneously dividing the substrate from the processed region by the internal stress of the substrate.

According to this method of manufacturing a nitride semiconductor device, the processed region (modified region) is previously formed in the substrate with the laser beam, and the substrate is thereafter divided through the internal stress of the substrate itself in the process of reducing the thickness of the substrate. Therefore, the substrate may not be handled in the state reduced in thickness (before dividing), whereby breakage resulting from handling of a thin substrate can be suppressed or prevented. Thus, the steps are stabilized, and the yield can be improved.

The substrate may be a sapphire substrate or an SiC substrate. The sapphire substrate or the SiC substrate causes remarkable stress when the group III nitride semiconductor layer is formed on the surface thereof. Thus, the substrate can be spontaneously divided from the processed region, by reducing the thickness of the substrate.

When the sapphire substrate is employed, the laser beam preferably has a wavelength (355 nm, for example) capable of causing multiphoton absorption in the sapphire substrate. When the SiC substrate is employed, on the other hand, the laser beam preferably has a wavelength (532 nm, for example) capable of causing multiphoton absorption in the SiC substrate.

The foregoing and other objects, features and effects of the present invention will become more apparent from the following detailed description of the preferred embodiments with reference to the attached drawings.

### BRIEF DESCRIPTION OF THE DRAWINGS

FIG. 1 is a schematic perspective view of a sapphire wafer employed in the steps of manufacturing a nitride semiconductor device according to an embodiment of the present invention.

FIGS. 2(a), 2(b) and 2(c) are schematic sectional views for illustrating the manufacturing steps.

### DETAILED DESCRIPTION OF PREFERRED EMBODIMENTS

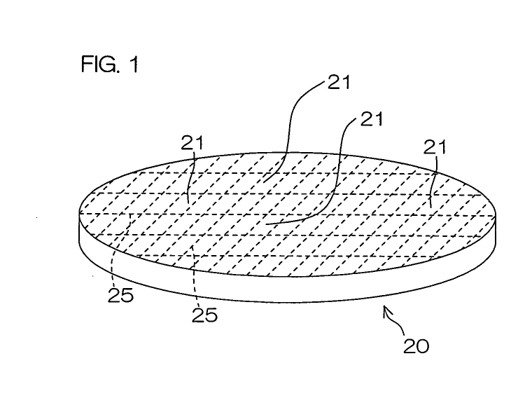

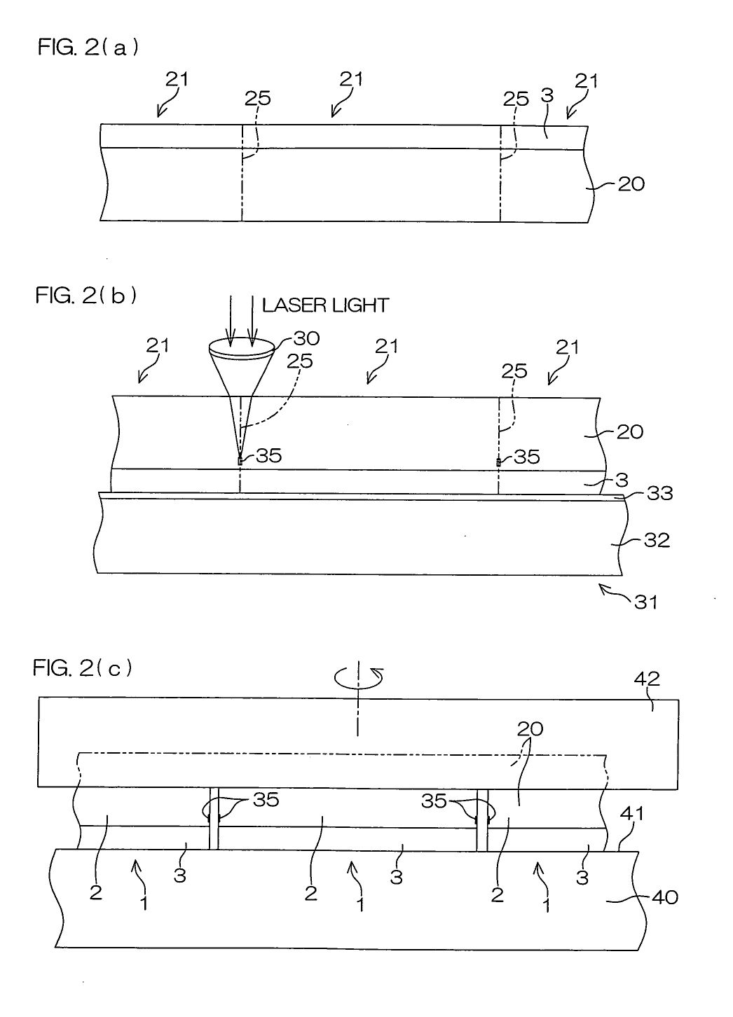

FIG. 1 is a schematic perspective view of a sapphire wafer employed in the steps of manufacturing a nitride semiconductor device according to an embodiment of the present invention. FIGS. 2(a) to 2(c) are schematic sectional views for illustrating the manufacturing steps.

A plurality of individual devices 21 each corresponding to a nitride semiconductor device chip 1 are collectively formed on a sapphire wafer 20. In other words, a group III nitride semiconductor layer 3 is epitaxially grown on the surface of the sapphire wafer 20, as shown in FIG. 2(a). Thereafter electrodes, etc. (not shown) are formed in contact with the group III nitride semiconductor layer 3, if necessary. Thus, the plurality of individual devices 21 are formed on the sapphire wafer 20.

In order to prepare a light emitting diode, for example, the group III nitride semiconductor layer 3 is formed by successively epitaxially growing an n-type GaN buffer layer (4 μm, for example) in contact with the sapphire wafer 20, an n-type GaN contact layer (1 μm to 10 μm, for example) stacked on the n-type GaN buffer layer, an active layer (light emitting layer) stacked on the n-type GaN contact layer and a p-type GaN contact layer (0.2 μm to 1 μm, for example) stacked on the active layer. For example, the active layer may have an MQW (multiple quantum well) structure (having a thickness of 0.05 μm to 0.3 μm in total, for example) formed by alternately stacking quantum well layers consisting of InGaN layers (1 nm to 3 nm each, for example) and barrier layers consisting of non-doped GaN layers (10 nm to 20 nm each, for example) in a repetitive manner (3 to 8 cycles, for example).

Then, a wafer dividing step for dividing the sapphire wafer 20 along cutting lines 25 defining the boundaries between the individual devices 21. The wafer dividing step includes a laser processing step (see FIG. 2(b)) of processing the sapphire wafer 20 with a laser beam along the cutting lines 25 and a thickness reduction/dividing step (see FIG. 2 (c)) of reducing the thickness of the sapphire wafer 20 and simultaneously spontaneously dividing the sapphire wafer 20 by the stress thereof.

In the laser processing step, a laser processor applies a laser beam to the sapphire wafer 20 provided with the group III nitride semiconductor layer 3, as shown in FIG. 2(b). While detailed illustration is omitted, the laser processor includes a laser beam generating unit, a converging lens 30 converging the laser beam generated by the laser beam generating unit in the sapphire wafer 20 and an X-Y stage mechanism 31 carrying the wafer 20.

The laser beam generating unit includes a laser source such as a YAG laser or an excimer laser, for example, and an optical system converting the laser beam emitted from this laser source to a parallel beam. The converging lens 30 converges the parallel laser beam received from the laser beam generating unit. The relation between the converging lens 30 and the sapphire wafer 20 is adjusted such that the focal position of the converging lens 30 is located in the sapphire wafer 20, more specifically on a portion left after the thickness of the sapphire wafer 20 is reduced in the thickness reduction/dividing step. This adjustment may be performed by adjusting the focal length of the converging lens 30, or by adjusting the distance between the converging lens 30 and the sapphire wafer 20. The distance between the converging lens 30 and the sapphire wafer 20 may be adjusted by approximating/separating the converging lens 30 to/from a stage 32 of the X-Y stage mechanism 31, or by approximating/separating the stage 32 of the X-Y stage mechanism 31 to/from the converging lens 30.

The X-Y stage mechanism 31 includes the stage 32 carrying the wafer 20 on a position opposed to the converging lens 30 and a stage moving mechanism two-dimensionally moving the stage 32 along a direction X and a direction Y orthogonal thereto. Both of the directions X and Y are along a horizontal plane, for example. The X-Y stage mechanism 31 may further include a mechanism moving the stage 32 along a direction Z (vertical direction, for example) for approximating/separating the stage 32 to/from the converging lens 30, if necessary. The wafer 20 is fixed to a receiving surface of the stage 32 through a support sheet 33 while opposing the side of the group III nitride semiconductor layer 3 to the stage 32. The support sheet 33 has pressure-sensitive adhesive layers on both surfaces thereof, for example.

The laser beam generating unit generates a laser beam having a wavelength (355 nm, for example) capable of causing multiphoton absorption in sapphire, for example. Further, the laser beam generating unit generates the laser beam at an intensity such that the laser beam is not absorbed on portions other than that close to the focal position of the converging lens 30 but multiphoton absorption is caused on the focal position. More specifically, the output of the laser beam generating unit may be adjusted such that the energy density of the laser beam on the focal position of the converging lens 30 is in the range of 5.0×10⁹ W/cm² to 2.0×10¹⁰ W/cm². Thus, multiphoton absorption can be reliably caused on the focal position. Further, the output of the laser beam generating unit is preferably adjusted such that the energy density in the group III nitride semiconductor layer 3 and on the surface of the sapphire wafer 20 is not more than 1.0×10⁷ W/cm². Thus, absorption of the laser beam on the positions other than the focal position can be avoided, where by the surface of the sapphire wafer 20 can be prevented from processing and the group III nitride semiconductor layer 3 can be prevented from formation of a processed region.

While the laser processor applies the laser beam to the wafer 20, the wafer 20 is relatively moved with respect to the position irradiated with the laser beam, to move the position irradiated with the laser beam moves along each cutting line 25. In other words, the X-Y stage mechanism 31 moves the wafer 20 in the direction along the cutting line 25. Thus, the laser beam scans the wafer 20 along the cutting line 25. Consequently, the focal position of the converging lens 30 moves along the cutting line 25 in a region of the sapphire wafer 20 close to the group III nitride semiconductor layer 3, to form a processed region (modified region) 35 corresponding to the locus of the focal position. The processed region 35 has a thickness of 2 μm to 3 μm, for example, in the thickness direction of the sapphire wafer 20.

In the scanning process, the laser beam may be regularly applied to the wafer 20, or the laser beam generating unit may be on-off controlled so as to intermittently apply the laser beam. The processed region 35 is continuously formed if the laser beam is regularly applied in the scanning process, while a plurality of processed regions 35 divided in a perforated manner at prescribed intervals in the scanning direction are formed along the cutting lines 25 if the laser beam is intermittently applied in the scanning process.

Then, the thickness reduction/dividing step shown in FIG. 2(c) is carried out. The sapphire wafer 20 ha sa thickness of 350 μm in the state not yet reduced in thickness, and the group III nitride semiconductor layer 3 having a thickness of about 3 μm to 5 μm, for example, is epitaxially grown on the major surface thereof. There after the thickness of the sapphire wafer 20 is reduced to about 80 μm, for example. The thickness of the sapphire wafer 20 can be reduced by grinding or polishing (chemical mechanical polishing or the like).

FIG. 2(c) shows an apparatus for reducing the thickness of the sapphire wafer 20 with a grinder. The sapphire wafer 20 is fixed onto a receiving surface 41 of a holder 40. More specifically, wax is applied onto the receiving surface 41, and the sapphire wafer 20 is directed downward to oppose the group III nitride semiconductor layer 3 to the receiving surface 41 and pressed against the receiving surface 41, for example. Thus, the wafer 20 can be fixed to the holder 40. Alternatively, the wafer 20 may be fixed to the receiving surface 41 with a carrier tape having pressure-sensitive adhesive layers on both surfaces thereof, in place of the wax.

Then, a discoidal grindstone 42 of the grinder is rotated and pressed against the back surface of the sapphire wafer 20 (major surface opposite to the group III nitride semiconductor layer 3). Thus, the sapphire wafer 20 is ground from the side of the back surface thereof, and reduced in thickness. Referring to FIG. 2(c), the two-dot chain lines show the thickness of the sapphire wafer 20 in the state not yet reduced in thickness.

In the process of reducing thickness, cracks are formed from the laser-processed regions 35 due to the internal stress of the sapphire wafer 20 itself, to spontaneously divide the sapphire wafer 20. Thus, the sapphire wafer 20 is divided into the sapphire substrate 2 in every individual device 21, and the group III nitride semiconductor layer 3 is also divided correspondingly thereto. A plurality of nitride semiconductor device chips 1 are obtained in this manner. Thus, the sapphire wafer 20 can be reduced in thickness and divided through the same step.

The internal stress of the sapphire wafer 20 itself is going to deform the sapphire wafer 20 into a bent shape convexed on the side of the group III nitride semiconductor layer 3. Therefore, the cracks are easily formed from the processed regions 35 formed around the group III nitride semiconductor layer 3. Thus, the sapphire wafer 20 can be reliably spontaneously divided in the process of the thickness reduction.

After the sapphire wafer 20 is divided, each chip 1 is detached from the holder 40. If the sapphire wafer 20 is fixed by wax, the chip 1 can be easily detached from the holder 40 by heating the wax to a temperature of about 100° C. and melting the same, for example. When the sapphire wafer 20 is fixed by a carrier tape, on the other hand, the carrier tape may be detached from the holder 40 and stretched by another stretcher, for detaching each chip 1 from this carrier tape.

In order to remove scraps resulting from the grinding, the chip 1 may be dipped in an alkaline washing solution, for example, for removing the scraps from the surface thereof. When the sapphire wafer 20 is fixed to the holder 40 with the carrier tape, the plurality of chips 1 may be dipped in the alkaline washing solution along with the carrier tape, to be detached from the carrier tape after the scraps are removed.

According to this embodiment, as hereinabove described, the thickness of the sapphire wafer 20 is reduced after the laser-processed regions 35 are previously formed on the sapphire wafer 20. Thus, the sapphire wafer 20 is spontaneously divided into the individual chips 1 in the process of reducing the thickness of the sapphire wafer 20, due to the internal stress thereof. Therefore, no robot and the like may be required for handling a thin wafer, whereby the wafer is not cracked during handling. Thus, the manufacturing steps are stabilized, and the yield can be improved.

Individual chip 1 has the laser-processed regions 35 on the chip end faces at the intermediate positions in the thickness direction of the sapphire substrate 2. The chip end faces are spontaneously divided surfaces formed by the spontaneous division of the sapphire wafer 20. The surface of the sapphire substrate 2 opposite to the group III nitride semiconductor layer 3 is a ground or polished surface.

While the embodiment of the present invention has been described, the present invention may be embodied in other ways. For example, while the laser beam is applied from the side of the back surface of the sapphire wafer 20 in the aforementioned embodiment, the laser beam may alternatively be applied from the surface of the sapphire wafer 20 closer to the group III nitride semiconductor layer 3, to be transmitted through the group III nitride semiconductor layer 3 and converged in the sapphire wafer 2.

While the chip 1 has the group III nitride semiconductor layer 3 formed on the sapphire substrate 2 in the aforementioned embodiment, another substrate such as an SiC substrate can alternatively be employed.

While the present invention is applied to manufacturing of a nitride semiconductor chip constituting a light emitting diode in the aforementioned embodiment, the present invention is also applicable to another light emitting device such as a semiconductor laser chip. Further, the present invention is not restricted to the light emitting device, but is also applicable to manufacturing of a transistor such as a power transistor or a high electron mobility transistor.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2007-196423 filed in the Japanese Patent Office on Jul. 27, 2007, the disclosure of which is incorporated herein by reference in its entirety.

What is claimed is:

1. A method of manufacturing a nitride semiconductor device, comprising the steps of:
growing a group III nitride semiconductor layer on a substrate;
forming a processed region in the substrate with a laser beam; and
reducing a thickness of the substrate thereby spontaneously dividing the substrate from the processed region by an internal stress of the substrate.

2. The method of manufacturing a nitride semiconductor device according to claim 1, wherein
the substrate is a sapphire substrate or an SiC substrate.

3. The method of manufacturing a nitride semiconductor device according to claim 1, wherein
the laser beam has a wavelength capable of causing multiphoton absorption in the substrate.

4. The method of manufacturing a nitride semiconductor device according to claim 1, wherein
the step of forming the processed region in the substrate with the laser beam includes a step of converging the laser beam in the substrate with a converging lens.

5. The method of manufacturing a nitride semiconductor device according to claim 4, wherein
a focal position of the converging lens is set in the substrate.

6. The method of manufacturing a nitride semiconductor device according to claim 5, wherein
the focal position of the converging lens is set in a portion left after reduction of the thickness of the substrate in the step of reducing the thickness of the substrate.

7. The method of manufacturing a nitride semiconductor device according to claim 5, wherein
an intensity of the laser beam is set such that multiphoton absorption is caused on the focal position of the converging lens and the laser beam is substantially not absorbed on positions other than that close to the focal position.

8. The method of manufacturing a nitride semiconductor device according to claim 1, wherein
the step of reducing the thickness of the substrate includes the steps of fixing a side of the substrate provided with the group III nitride semiconductor layer to a holder and grinding or polishing a side of the substrate opposite to the group III nitride semiconductor layer.

9. A nitride semiconductor device including:
a substrate;
a group III nitride semiconductor layer formed on the substrate; and
a laser-processed region formed on a device end face at an intermediate position in a thickness direction of the substrate.

10. The nitride semiconductor device according to claim 9, wherein
the device end face is a spontaneously divided surface formed by spontaneous division resulting from an internal stress of the substrate.

11. The nitride semiconductor device according to claim 9, wherein
the surface of the substrate opposite to the group III nitride semiconductor layer is a ground or polished surface.
